(19) United States
(12) Patent Application Publication
(10) Pub. No.: US 2023/0140124 A1
(43) Pub. Date: May 4, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: Wei WAN, Hefei City (CN)

(21) Appl. No.: 17/453,527

(22) Filed: Nov. 4, 2021

(51) Int. Cl. H01L 29/423; H01L 29/78; H01L 29/66

(52) U.S. Cl. CPC H01L 29/4236; H01L 29/7827; H01L 29/66666

(57) ABSTRACT

The present disclosure provides a semiconductor structure and a manufacturing method thereof. The semiconductor structure includes: a substrate; a channel groove, located in the substrate; and a fin, located on a bottom wall of the channel groove, wherein the fin protrudes towards an inner side of the channel groove, and a gap is provided between the fin and each sidewall of the channel groove, wherein the sidewall of the channel groove includes a connection surface and a step surface, and the step surface includes at least one step unit.

### CROSS-REFERENCE TO RELATED APPLICATIONS

This is a continuation of International Application No. PCT/CN2021/110726, filed on Aug. 5, 2021, which claims the priority to Chinese Patent Application 202110753754.4, titled “SEMICONDUCTOR STRUCTURE AND MANUFACTURING METHOD THEREOF” and filed on Jul. 2, 2021. The entire contents of International Application No. PCT/CN2021/110726 and Chinese Patent Application 202110753754.4 are incorporated herein by reference.

### TECHNICAL FIELD

The present disclosure relates to, but is not limited to, a semiconductor structure and a manufacturing method thereof.

### BACKGROUND

Dynamic random access memory (DRAM) is a semiconductor memory widely applied to electronic products such as mobile phones, computers, and automobiles. With the development of science and technology, the feature size of integrated circuit devices shrinks continuously, and the size of key positions of the DRAM is also becoming smaller, which requires higher electrical performance of the DRAM.

Currently, gates of active regions of the DRAM are mostly buried gates, which are small in size. A smaller gate size is more likely to cause a short-channel effect.

### SUMMARY

An overview of the subject matter detailed in the present disclosure is provided below, which is not intended to limit the protection scope of the claims.

The present disclosure provides a semiconductor structure and a manufacturing method thereof.

According to a first aspect, the present disclosure provides a semiconductor structure, including:
a substrate;
a channel groove, located in the substrate; and
a fin, located on a bottom wall of the channel groove, wherein the fin protrudes towards an inner side of the channel groove, and a gap is provided between the fin and each sidewall of the channel groove;
wherein the sidewall of the channel groove includes a connection surface and a step surface, and the step surface includes at least one step unit.

According to a second aspect, the present disclosure provides a method of manufacturing a semiconductor structure, including:
providing a substrate;
forming an accommodation groove in the substrate; and
forming a fin on a bottom wall of the accommodation groove, wherein the fin protrudes towards an inner side of the accommodation groove.

Other aspects of the present disclosure are understandable upon reading and understanding of the drawings and detailed description.

### BRIEF DESCRIPTION OF THE DRAWINGS

The drawings incorporated into the specification and constituting part of the specification illustrate the embodiments of the present disclosure, and are used together with the description to explain the principles of the embodiments of the present disclosure. In these drawings, similar reference numerals are used to represent similar elements. The drawings in the following description are part rather than all of the embodiments of the present disclosure. Those skilled in the art may derive other drawings based on these drawings without creative efforts.

FIG. 1 is a schematic diagram of a semiconductor structure according to a comparative example;

FIG. 2 is a schematic diagram of a semiconductor structure according to a comparative example;

FIG. 3 is a schematic diagram of a semiconductor structure according to an exemplary embodiment;

FIG. 4 is a schematic diagram of a semiconductor structure according to an exemplary embodiment;

FIG. 5 is a schematic diagram of a semiconductor structure according to an exemplary embodiment;

FIG. 6 is a schematic diagram of a semiconductor structure according to an exemplary embodiment;

FIG. 7 is a flowchart of a method of manufacturing a semiconductor structure according to an exemplary embodiment;

FIG. 8 is a flowchart of a method of manufacturing a semiconductor structure according to an exemplary embodiment;

FIG. 9 is a flowchart of a method of manufacturing a semiconductor structure according to an exemplary embodiment;

FIG. 10 is a flowchart of a method of manufacturing a semiconductor structure according to an exemplary embodiment;

FIG. 11 is a schematic diagram of an initial structure in a method of manufacturing a semiconductor structure according to an exemplary embodiment;

FIG. 12 is a schematic diagram of forming an initial channel groove in a method of manufacturing a semiconductor structure according to an exemplary embodiment;

FIG. 13 is a schematic diagram of forming a first oxide layer in a method of manufacturing a semiconductor structure according to an exemplary embodiment;

FIG. 14 is a schematic diagram of etching a first oxide layer and exposing a part of a substrate in an initial channel groove in a method of manufacturing a semiconductor structure according to an exemplary embodiment;

FIG. 15 is a schematic diagram of forming a process channel groove in a method of manufacturing a semiconductor structure according to an exemplary embodiment;

FIG. 16 is a schematic diagram of forming a second oxide layer in a method of manufacturing a semiconductor structure according to an exemplary embodiment;

FIG. 17 is a schematic diagram of etching a second oxide layer and forming an accommodation groove in a method of manufacturing a semiconductor structure according to an exemplary embodiment;

FIG. 18 is a schematic diagram of forming an initial fin in a method of manufacturing a semiconductor structure according to an exemplary embodiment;

FIG. 19 is a schematic diagram of removing an initial fin and forming a fin in a method of manufacturing a semiconductor structure according to an exemplary embodiment;

FIG. 20 is a schematic diagram of removing a first oxide layer and a second oxide layer and forming a channel groove in a method of manufacturing a semiconductor structure according to an exemplary embodiment;

FIG. 21 is a schematic diagram of forming a third oxide layer in a method of manufacturing a semiconductor structure according to an exemplary embodiment;

FIG. 22 is a schematic diagram of forming a barrier layer in a method of manufacturing a semiconductor structure according to an exemplary embodiment; and

FIG. 23 is a schematic diagram of forming a gate in a method of manufacturing a semiconductor structure according to an exemplary embodiment.

### REFERENCE NUMERALS

10. substrate;

20. channel groove; 200. accommodation groove; 210. initial channel groove; 211. process channel groove; 21. bottom wall of channel groove; 22. sidewall of channel groove; 221. step surface; 220. step unit; 2201. first surface; 2202. second surface; 222. connection surface;

30. fin; 31. gap; 300. fin unit;

40. third oxide layer;

50. barrier layer; 500. second oxide layer;

60. gate;

400. first oxide layer;

80. etching barrier layer;

90. photoresist mask; 901. pattern;

10′. substrate; 20′. channel groove; 100′. buried gate; 21′. bottom wall; 22′. sidewall.

### DETAILED DESCRIPTION

The technical solutions in the embodiments of the present disclosure are described below clearly and completely with reference to the drawings in the embodiments of the present disclosure. Apparently, the described embodiments are merely part rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

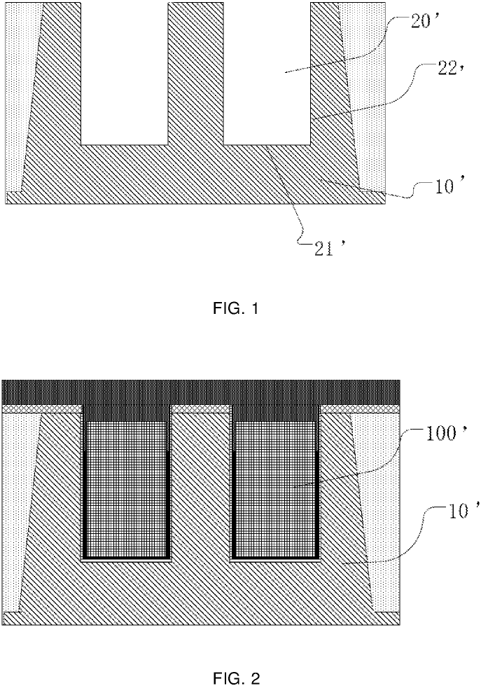

As shown in FIG. 2 with reference to FIG. 1, a buried gate structure at present includes a substrate 10′ and a channel groove 20′ located in the substrate 10′, as well as a buried gate 100′ provided in the channel groove 20′. As shown in FIG. 1, the channel groove 20′ includes a bottom wall 21′ and sidewalls 22′ on both sides. The length of the channel groove 20′ is a sum of the length of the bottom wall 21′ and the lengths of the sidewalls 22′ on both sides.

With the miniaturization of integrated circuit devices, as the buried gate 100′ and the channel groove 20′ configured to set the buried gate 100′ become smaller, the length of the channel groove 20′ is reduced. When the length of the channel groove 20′ of a metal oxide semiconductor field-effect transistor decreases to the scale of dozens of nanometers or even a few nanometers, the transistor will have the problem of threshold voltage reduction. This is because when the length of the channel groove 20′ is reduced to a certain extent, the depletion area of the source and drain occupies a larger proportion of the whole channel groove 20′, and the amount of charge required for forming an inverse layer on the surface of the substrate 10′ below the buried gate 100′ decreases, which leads to a decrease in the threshold voltage and a short-channel effect.

Accordingly, the present disclosure provides a semiconductor structure. A fin is provided in a channel groove and a step surface is added on each sidewall of the channel groove, which increases the length of the channel groove, thereby solving the short-channel effect of the semiconductor structure and improving the stability and electrical performance of the semiconductor device.

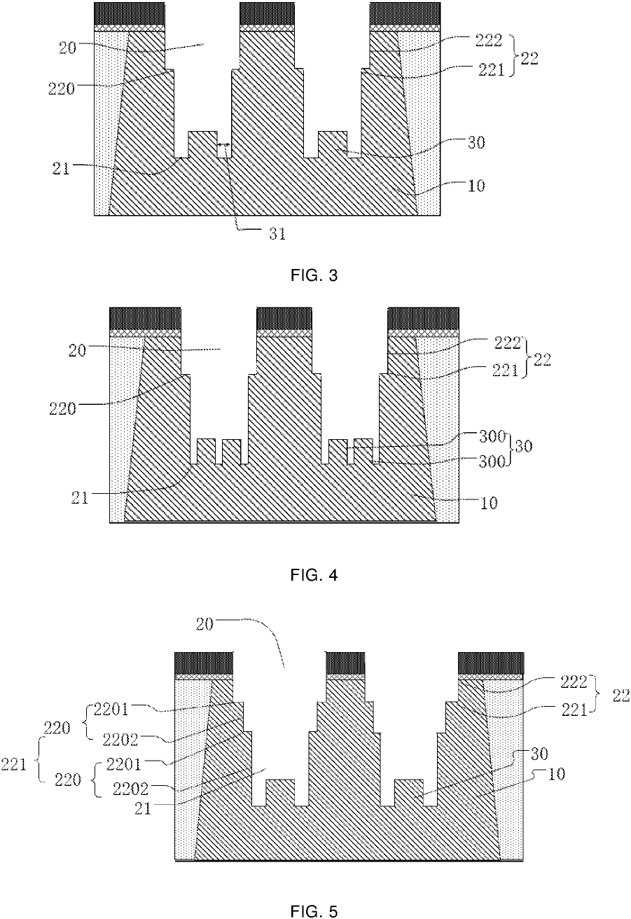

An exemplary embodiment of the present disclosure provides a semiconductor structure. As shown in FIG. 3, the semiconductor structure in this embodiment includes a substrate 10 and a channel groove 20 located in the substrate 10, as well as a fin 30 located on a bottom wall 21 of the channel groove 20. The fin 30 protrudes towards an inner side of the channel groove 20, and a gap 31 is provided between the fin 30 and each sidewall 22 of the channel groove 20.

In the semiconductor structure of this embodiment, by providing the protruding fin 30 in the channel groove 20, the surface area of the channel groove 20 is increased, which can solve the short-channel effect, thus solving the problem of threshold voltage reduction of the transistor caused by the short-channel effect, and improving the stability and electrical performance of the semiconductor device.

In addition, the sidewall 22 of the channel groove 20 of the semiconductor structure in this embodiment includes a connection surface 222 and a step surface 221, and the step surface 221 includes at least one step unit 220, which further increases the surface area of the channel groove 20.

In the semiconductor structure of this embodiment, the length of the channel groove is increased by improving the structure of the channel groove, to meet the requirements of miniaturization of integrated circuit devices. The length of the channel groove can still be ensured while the size of the channel groove is reduced, avoiding problems such as the short-channel effect and the consequential threshold voltage reduction while still ensuring the stability and electrical performance of the semiconductor device.

An exemplary embodiment of the present disclosure provides a semiconductor structure. As shown in FIG. 4, the semiconductor structure in this embodiment includes a substrate 10 and a channel groove 20 located in the substrate 10, as well as a fin 30 located on a bottom wall 21 of the channel groove 20. The fin 30 protrudes towards an inner side of the channel groove 20, and a gap is provided between the fin 30 and each sidewall 22 of the channel groove 20. The sidewall 22 of the channel groove 20 includes a connection surface 222 and a step surface 221, and the step surface 221 includes at least one step unit 220.

The fin 30 includes one or more fin units 300, and when more than one protruding fin units 300 are provided in the channel groove 20, a gap is formed between adjacent fin units 300, and a gap is formed between the fin unit 300 close to a sidewall 22 of the channel groove 20 and the sidewall 22 of the channel groove 20. In this embodiment, two fin units 300 are provided in one channel groove 20, and a gap is formed between the two fin units 300; a gap is formed between each fin unit 300 and its adjacent sidewall 22 of the channel groove 20, thus effectively increasing the length of the channel groove 20. In other possible embodiments, the fin 30 may include one fin unit 300, three fin units 300 or five fin units 300, etc.

In this embodiment, as shown in FIG. 4, a plane perpendicular to the substrate 10 is a longitudinal section, a shape of the fin unit 300 in the longitudinal section is square. For example, the fin unit 300 may be a cylindrical, rectangular, cubic or any other three-dimensional structure with a square-shaped longitudinal section.

In this embodiment, the size of the fin unit 300 can be set according to the size of the channel groove 20. For example, the height of the fin unit 300 is 10-30 nm, and the width of the fin unit 300 is 5-10 nm.

In this embodiment, multiple fin units are provided by making full use of the internal space of the channel groove, to further increase the length of the channel groove and avoid the problem of short-channel effect. The number of fin units can be set according to the size of the channel groove, to avoid an excessively short distance between adjacent fin units due to an increase in the number of fin units.

An exemplary embodiment of the present disclosure provides a semiconductor structure. As shown in FIG. 3, the semiconductor structure includes a substrate 10 and a channel groove 20 located in the substrate 10, as well as a fin 30 located on a bottom wall 21 of the channel groove 20. The fin 30 protrudes towards an inner side of the channel groove 20, and a gap is provided between the fin 30 and each sidewall 22 of the channel groove 20. The fin 30 may include one or more fin units 300, and when the fin 30 includes a plurality of fin units 300, a gap is provided between two adjacent fin units 300.

In this embodiment, the sidewall 22 of the channel groove 20 includes a connection surface 222 and a step surface 221, and the step surface 221 includes at least one step unit 220. The connection surface 222 is connected to the step surface 221, the connection surface 222 is connected to a top surface of the substrate 10, and the step surface 221 is connected to the bottom wall 21 of the channel groove 20. Depending on the number of step units 220 in the step surface 221, multiple grooves of different widths and depths are formed along a direction perpendicular to the substrate 10.

In this embodiment, the size of the step unit 220 is set according to the size of the channel groove 20. For example, the length of the connection surface 222 may be 20-60 nm, and the width of the first surface 2201 of the step unit 220 is 2-8 nm. In this embodiment, when the channel groove 20 includes multiple step units 220, the length of the second surface 2202 of the lowermost step unit 220 is greater than the height of the fin 30 along the direction perpendicular to the substrate 10.

In this embodiment, a projection of the bottom wall 21 of the channel groove 20 on the substrate 10 is located within a projection of a notch of the channel groove 20 on the substrate. That is, the width of an upper groove is greater than the width of a lower groove along the direction shown in FIG. 3. In addition, the multiple step units 220 are connected in sequence to form multiple step surfaces on the sidewalls of the channel groove 20, thus increasing the length of the channel groove 20.

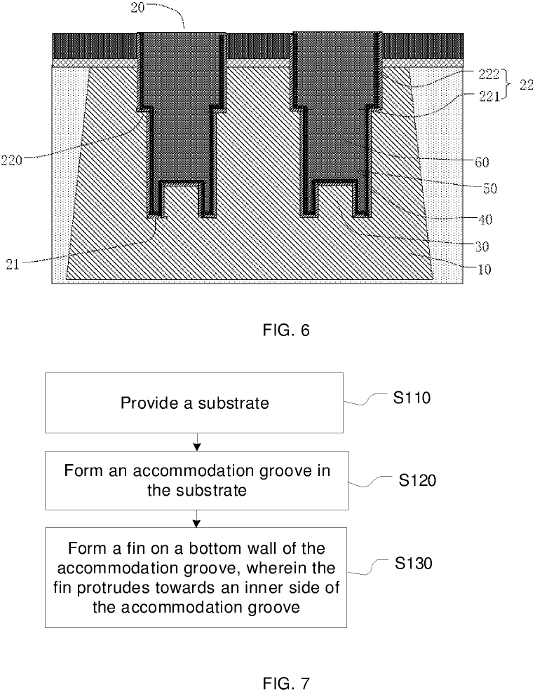

An exemplary embodiment of the present disclosure provides a semiconductor structure. As shown in FIG. 5, the semiconductor structure includes a substrate 10 and a channel groove 20 located in the substrate 10, as well as a fin 30 located on a bottom wall 21 of the channel groove 20. The fin 30 protrudes towards an inner side of the channel groove 20, and a gap is provided between the fin 30 and each sidewall 22 of the channel groove 20. The fin 30 includes one or more fin units 300; when the fin 30 includes a plurality of fin units 300, a gap is provided between two adjacent fin units 300. The sidewall 22 of the channel groove 20 includes a connection surface 222 and a step surface 221, and the step surface 221 includes at least one step unit 220. In this embodiment, the connection surface 222 is connected to the step surface 221, the connection surface 222 is connected to a top surface 11 of the substrate 10, and the step surface 221 is connected to the bottom wall of the channel groove.

As shown in FIG. 5, the step surface 221 includes multiple step units 220 connected end to end; the step unit 220 includes a first surface 2201 and a second surface 2202 connected to each other, wherein the first surface 2201 is parallel to the substrate 10, and the second surface 2202 is perpendicular to the substrate 10. The second surface 2202 of the step unit 220 is connected to the bottom wall 21, or connected to the first surface 2201 of the adjacent step unit 220. The first surface 2201 of the step unit 220 is connected to the connection surface 222, or connected to the second surface 2202 of the adjacent step unit 220.

In this embodiment, a projection of the first surface 2201 of the step unit 220 on the substrate 10 is located outside a projection of the bottom wall of the channel groove 20 on the substrate 10. A total area of the projections of one or more first surfaces 2201 on the substrate 10 and the projection of the bottom wall 21 on the substrate 10 is equal to an area of a projection of a notch of the channel groove 20 on the substrate 10.

The number of step units 220 is set according to the size of the channel groove 20, wherein two step units 220, three step units 220, four step units 220, or five step units 220, etc. can be provided in the channel groove 20. As shown in FIG. 5, in the semiconductor structure of this embodiment, two step units 220 are formed on each sidewall 22 of the channel groove 20, and along the direction perpendicular to the substrate 10, the two step units 220 of each sidewall 22 of the channel groove 20 are defined to be two grooves with different widths and depths.

In this embodiment, multiple step units are provided by making full use of the internal space of the channel groove, to further increase the length of the channel groove and avoid the problem of short-channel effect.

An exemplary embodiment of the present disclosure provides a semiconductor structure. As shown in FIG. 6, the semiconductor structure in this embodiment includes a substrate 10 and a channel groove 20 located in the substrate 10, as well as a fin 30 located on a bottom wall 21 of the channel groove 20. The fin 30 protrudes towards an inner side of the channel groove 20, and a gap is provided between the fin 30 and each sidewall 22 of the channel groove 20. The sidewall 22 of the channel groove 20 includes a connection surface 222 and a step surface 221, and the step surface 221 includes at least one step unit 220.

As shown in FIG. 6, the semiconductor structure in this embodiment further includes: a third oxide layer 40 covering the bottom wall 21 and sidewalls 22 of the channel groove 20 as well as an outer surface of the fin 30, a barrier layer 50 covering a bottom wall and partial sidewalls of the third oxide layer 40, and a gate 60 covering a bottom wall and sidewalls of the barrier layer 50.

In the semiconductor structure of this embodiment, the length of the channel groove 20 as well as the contact area between the gate 60 and the substrate 10 is increased, which can avoid the problem of short-channel effect.

The semiconductor structure according to the embodiments of the present disclosure can be used for a transistor; the semiconductor structure according to the embodiments of the present disclosure can be included in a memory cell and a memory cell array. The memory array may be included in a memory device. The memory device can be used in a dynamic random access memory (DRAM). The memory device can also be used in a static random access memory (SRAM), a flash memory, a ferroelectric random access memory (FeRAM), a magnetic random access memory (MRAM), a phase change random access memory (PRAM), etc.

An exemplary embodiment of the present disclosure provides a method of manufacturing a semiconductor structure, as shown in FIG. 7. FIG. 7 is a flowchart of a method of manufacturing a semiconductor structure according to an exemplary embodiment of the present disclosure. FIG. 11 to FIG. 23 are schematic diagrams of various stages of the method of manufacturing a semiconductor structure. The method of manufacturing a semiconductor structure is described below with reference to FIG. 11 to FIG. 23.

As shown in FIG. 7, the method of manufacturing a semiconductor structure in this embodiment includes:

S110: Provide a substrate.

The structure of the substrate 10 is shown in FIG. 11; the substrate 10 may be a semiconductor substrate includes a silicon-containing substance. The semiconductor substrate may include a silicon substrate, a SiGe substrate, or a silicon on insulator (SOI) substrate.

S120: Form an accommodation groove in the substrate.

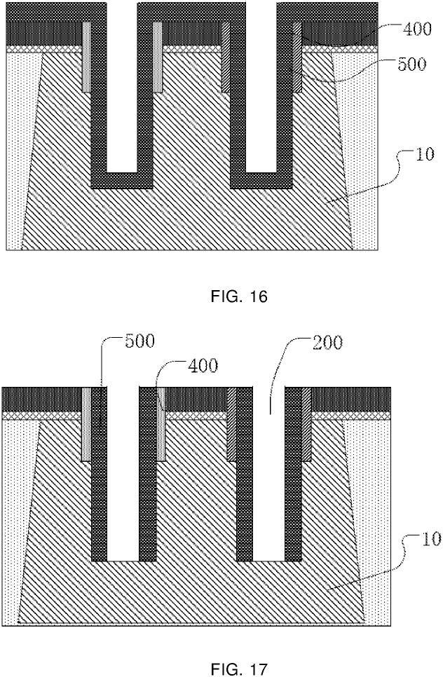

As shown in FIG. 17, the accommodation groove 200 is an intermediate structure formed during an intermediate process of forming a channel groove 20. The accommodation groove 200 is defined by a first oxide layer 400, a second oxide layer 500 and the substrate 10. The second oxide layer 500 and the first oxide layer 400 surround the sidewalls of the accommodation groove 200 in order. The second oxide layer 500 and the first oxide layer 400 have different dimensions along a thickness direction of the substrate 10.

S130: Form a fin on a bottom wall of the accommodation groove, wherein the fin protrudes towards an inner side of the accommodation groove.

As shown in FIG. 19, the fin 30 is formed at the bottom of the accommodation groove 200, a bottom wall of the fin 30 is connected to the substrate 10, and the fin 30 protrudes by a predetermined length towards the inside of the accommodation groove 200. The predetermined length can be set according to requirements in a real-time process.

A material of the fin 30 includes a silicon-containing substance. For example, the material of the fin 30 may be silicon oxide, silicon nitride, silicon oxynitride or silicon germanide. In this embodiment, the material of the fin 30 is the same as the material of the substrate 10.

According to the method of manufacturing a semiconductor structure in this embodiment, the fin is formed in the channel groove, which increases the length of the channel groove and can avoid the problem of short-channel effect of the semiconductor structure, thus avoiding problems such as threshold voltage reduction of the transistor caused by the short-channel effect of the semiconductor structure, and further improving the stability and electrical performance of the semiconductor device.

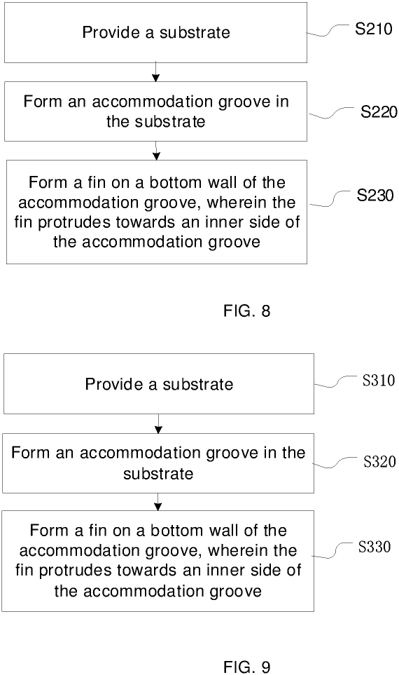

An exemplary embodiment of the present disclosure provides a method of manufacturing a semiconductor structure, as shown in FIG. 8. FIG. 8 is a flowchart of a method of manufacturing a semiconductor structure according to an exemplary embodiment of the present disclosure.

As shown in FIG. 8, the method of manufacturing a semiconductor structure in this embodiment includes:
S210: Provide a substrate.
S220: Form an accommodation groove in the substrate.
S230: Form a fin on a bottom wall of the accommodation groove, wherein the fin 30 protrudes towards an inner side of the accommodation groove 200.

In this embodiment, steps S210 and S230 of this embodiment are implemented in the same manner as steps S110 and S130 in the foregoing embodiment, and will not be described in detail again herein.

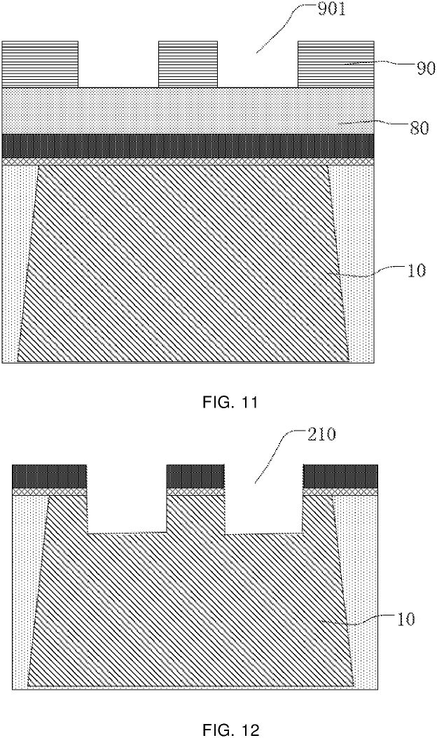

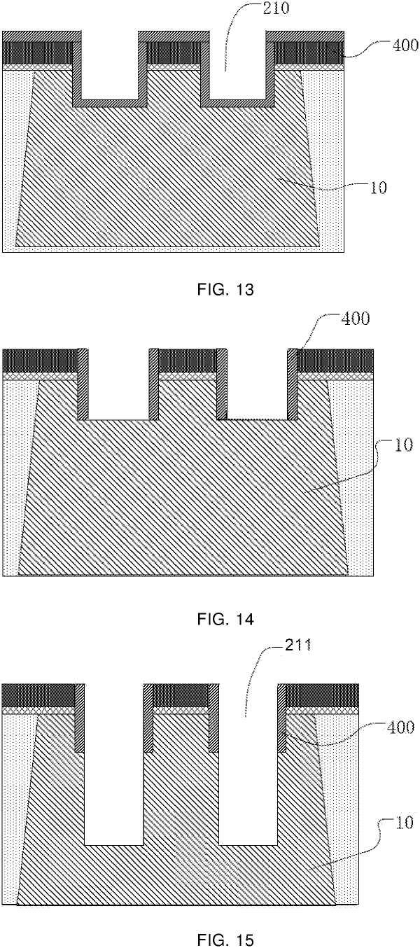

Formation of an etching barrier layer 80 on the substrate 10 includes: as shown in FIG. 12 with reference to FIG. 11, etching the etching barrier layer 80 and the substrate 10 based on a defined pattern 901, and form an initial channel groove 210 in the substrate 10; as shown in FIG. 14 with reference to FIG. 13, forming a first oxide layer 400, wherein the first oxide layer 400 covers at least a bottom wall and sidewalls of the initial channel groove 210; removing a part of the first oxide layer 400 covering the bottom wall of the initial channel groove 210 and expose a part of the substrate 10; etching the exposed substrate 10, as shown in FIG. 15, and form a process channel groove 211; as shown in FIG. 17 with reference to FIG. 16, forming a second oxide layer 500, wherein the second oxide layer 500 covers at least a bottom wall and sidewalls of the process channel groove 211; removing a part of the second oxide layer 500 covering the bottom wall of the process channel groove 211 and form the accommodation groove 200.

As shown in FIG. 11 and FIG. 12, a photoresist mask 90 is formed on the etching barrier layer 80, and a pattern 901 with a predefined shape is defined on the photoresist mask 90. The etching barrier layer 80 and the substrate 10 are etched according to the pattern 901 defined on the photoresist mask 90, and form an initial channel groove 210. The pattern 901 defined on the photoresist mask 90 may be defined directly by illumination; alternatively, the pattern 901 may be defined first by illumination and then pitch doubling is performed. The method of defining the pattern 901 depends on the width of the channel groove.

The photoresist mask 90 includes a photoresist material. For example, the photoresist mask 90 includes photoresist/SION/Carbon/SOC/SiO2/DARK, and the thickness of the photoresist mask 90 is 20-250 nm.

Referring to FIG. 13 and FIG. 14, the first oxide layer 400 may be deposited by atomic layer deposition (ALD). The first oxide layer 400 covers the sidewalls and bottom wall of the initial channel groove 210 as well as the top surface of the substrate 10. A part of the first oxide layer 400 covering the top surface of the substrate 10 and the bottom wall of the initial channel groove 210 is removed by dry or wet etching, and expose a part of the substrate 10.

As shown in FIG. 16 with reference to FIG. 15, the second oxide layer 500 may be deposited by atomic layer deposition (ALD). The second oxide layer 500 covers the sidewalls and bottom wall of the process channel groove 211 as well as the top surface of the substrate 10. A part of the second oxide layer 500 covering the top surface of the substrate 10 and the bottom wall of the process channel groove 211 is removed by dry or wet etching, and expose a part of the substrate 10, and as shown in FIG. 17, the accommodation groove 200 is thus formed.

In the manufacturing method of this embodiment, the accommodation groove 200 of the semiconductor structure is formed in the process channel groove 211; along the direction perpendicular to the substrate 10, the process channel groove 211 is a structure in which the size of an upper groove is larger than that of a lower groove, which increases the length of the channel groove and avoids the short-channel effect in the semiconductor structure.

An exemplary embodiment of the present disclosure provides a method of manufacturing a semiconductor structure, as shown in FIG. 9. FIG. 9 is a flowchart of a method of manufacturing a semiconductor structure according to an exemplary embodiment of the present disclosure.

As shown in FIG. 9, the method of manufacturing a semiconductor structure in this embodiment includes:
S310: Provide a substrate.
S320: Form an accommodation groove in the substrate 10.
S330: Form a fin on a bottom wall of the accommodation groove, wherein the fin protrudes towards an inner side of the accommodation groove.

In this embodiment, steps S310 and S320 of this embodiment are implemented in the same manner as steps S210 and S220 in the foregoing embodiment, and will not be described in detail again herein.

As shown in FIG. 18, formation of the fin 30 on the bottom wall of the accommodation groove includes: forming an initial fin 3 on the bottom wall of the accommodation groove 200, wherein the initial fin 3 covers at least the accommodation groove 200; and as shown in FIG. 19, etching the initial fin 3 to form the fin 30.

As shown in FIG. 18, the formation of the initial fin 3 on the bottom wall of the accommodation groove 200 includes: depositing a polysilicon layer, wherein the polysilicon layer covers the accommodation groove 200 and a top wall of the substrate 10; and etching back the initial fin 3 to a predetermined height by dry or wet etching, to obtain the fin 30.

The fin 30 may include one or more fin units 300; the accommodation groove 200 corresponds to the fin unit in a one-to-one manner. That is, in step S320 of this embodiment, multiple accommodation grooves 200 are formed in the process channel groove 211, and one fin unit 300 is correspondingly formed in each accommodation groove 200; as shown in FIG. 4, multiple fin units 300 jointly form the fin 30 that exists in the final channel groove 20.

In this embodiment, the semiconductor structure has multiple fin units in the final channel groove, which makes full use of the internal space of the channel groove, thereby effectively increasing the length of the channel groove.

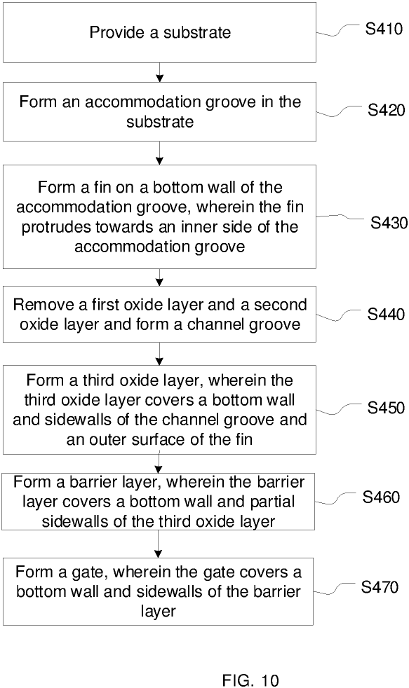

An exemplary embodiment of the present disclosure provides a method of manufacturing a semiconductor structure, as shown in FIG. 10. FIG. 10 is a flowchart of a method of manufacturing a semiconductor structure according to an exemplary embodiment of the present disclosure.

As shown in FIG. 10, the method of manufacturing a semiconductor structure in this embodiment includes:
S410: Provide a substrate.
S420: Form an accommodation groove in the substrate.
S430: Form a fin on a bottom wall of the accommodation groove, wherein the fin protrudes towards an inner side of the accommodation groove.
S440: Remove a first oxide layer and a second oxide layer and form a channel groove.
S450: Form a third oxide layer, wherein the third oxide layer covers a bottom wall and sidewalls of the channel groove and an outer surface of the fin.
S460: Form a barrier layer, wherein the barrier layer covers a bottom wall and partial sidewalls of the third oxide layer.
S470: Form a gate, wherein the gate covers a bottom wall and sidewalls of the barrier layer.

In this embodiment, steps S410 to S430 of this embodiment are implemented in the same manner as steps S310 to S330 of the foregoing embodiment, and will not be described in detail again herein.

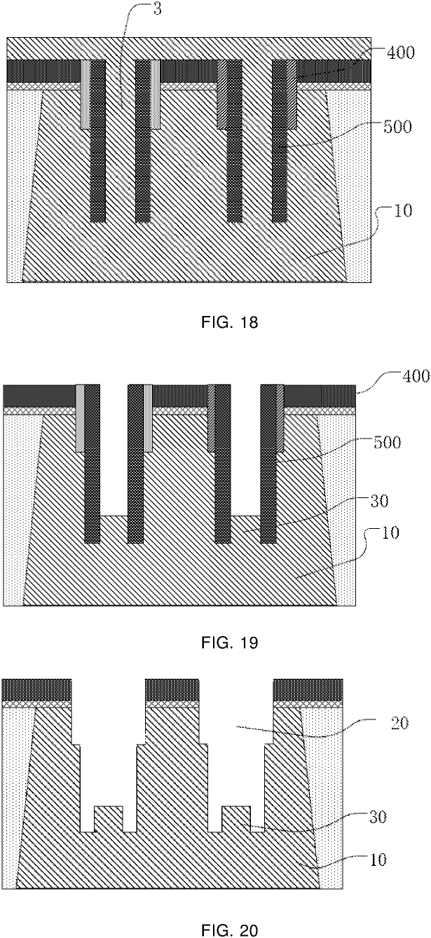

As shown in FIG. 20, the first oxide layer 400 and the second oxide layer 500 are removed to form the channel groove 20.

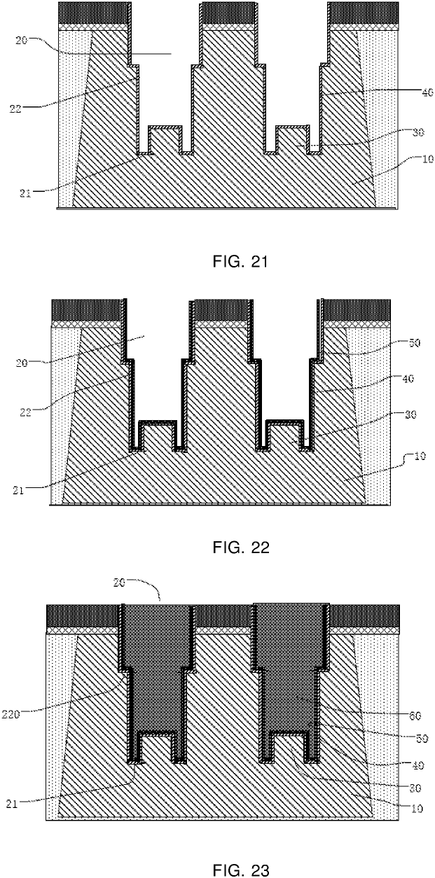

As shown in FIG. 21 with reference to FIG. 20, the third oxide layer 40 is deposited in the channel groove 20. The third oxide layer 40 covers the bottom wall 21 and sidewalls 22 of the channel groove 20 and the outer surface of the fin 30. As shown in FIG. 22, the barrier layer 50 is deposited, wherein the barrier layer 50 covers the bottom wall and partial sidewalls of the third oxide layer 40. As shown in FIG. 23, the gate 60 is deposited, wherein the gate 60 covers the bottom wall and sidewalls of the barrier layer 50.

The semiconductor structure manufactured in this embodiment can be used for a transistor, to avoid the short-channel effect and the consequential threshold voltage reduction or other problems.

Each embodiment or implementation in the specification of the present disclosure is described in a progressive manner. Each embodiment focuses on the difference from other embodiments, and the same and similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figuren. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### Industrial Applicability

In the semiconductor structure and the manufacturing method thereof provided in the embodiments of the present disclosure, a fin is provided in a channel groove and a step surface is added on each sidewall of the channel groove, which increases the length of the channel groove, thereby solving the short-channel effect of the semiconductor structure and improving the stability and electrical performance of the semiconductor device.

1. A semiconductor structure, comprising:
a substrate;
a channel groove, located in the substrate; and
a fin, located on a bottom wall of the channel groove, wherein the fin protrudes towards an inner side of the channel groove, and a gap is provided between the fin and each sidewall of the channel groove;
wherein the sidewall of the channel groove comprises a connection surface and a step surface, and the step surface comprises at least one step unit.

2. The semiconductor structure according to claim 1, wherein the fin comprises one or more fin units; and
when the fin comprises a plurality of the fin units, and a gap is provided between two adjacent fin units.

3. The semiconductor structure according to claim 2, wherein a plane perpendicular to the substrate is a longitudinal section, a shape of the fin unit in the longitudinal section is square.

4. The semiconductor structure according to claim 1, wherein
the connection surface is connected to the step surface, the connection surface is connected to a top surface of the substrate, and the step surface is connected to the bottom wall of the channel groove.

5. The semiconductor structure according to claim 4, wherein a projection of the bottom wall of the channel groove on the substrate is located within a projection of a notch of the channel groove on the substrate.

6. The semiconductor structure according to claim 4, wherein the step surface comprises a plurality of the step units, the plurality of the step units are connected end to end;
the step unit comprises a first surface and a second surface connected to each other, the first surface is parallel to the substrate, and the second surface is perpendicular to the substrate;
the second surface of the step unit is connected to the bottom wall, or connected to the first surface of an adjacent step unit; and
the first surface of the step unit is connected to the connection surface, or connected to the second surface of the adjacent step unit.

7. The semiconductor structure according to claim 6, wherein a projection of the first surface on the substrate is located outside a projection of the bottom wall of the channel groove on the substrate.

8. The semiconductor structure according to claim 6, wherein a total area of projections of one or more of the first surfaces on the substrate and a projection of the bottom wall on the substrate is equal to an area of a projection of a notch of the channel groove on the substrate.

9. The semiconductor structure according to claim 1, the semiconductor structure further comprising:
a third oxide layer, covering the bottom wall and the sidewalls of the channel groove and an outer surface of the fin;
a barrier layer, covering a bottom wall and partial sidewalls of the third oxide layer; and
a gate, covering a bottom wall and sidewalls of the barrier layer.

10. A method of manufacturing a semiconductor structure, comprising:
providing a substrate;
forming an accommodation groove in the substrate; and
forming a fin on a bottom wall of the accommodation groove, wherein the fin protrudes towards an inner side of the accommodation groove.

11. The method of manufacturing a semiconductor structure according to claim 10, wherein the forming an accommodation groove in the substrate comprises:
forming an etching barrier layer on the substrate;
etching the etching barrier layer and the substrate based on a defined pattern, and forming an initial channel groove in the substrate;
forming a first oxide layer, wherein the first oxide layer covers at least a bottom wall and sidewalls of the initial channel groove;
removing the first oxide layer covering the bottom wall of the initial channel groove, and exposing a part of the substrate;
etching exposed substrate and forming a process channel groove; and
forming a second oxide layer, wherein the second oxide layer covers at least a bottom wall and sidewalls of the process channel groove; and removing the second oxide layer covering the bottom wall of the process channel groove, and forming the accommodation groove.

12. The method of manufacturing a semiconductor structure according to claim 11, wherein the forming a fin on a bottom wall of the accommodation groove comprises:
forming an initial fin on the bottom wall of the accommodation groove, wherein the initial fin covers at least the accommodation groove; and
etching the initial fin, and forming the fin.

13. The method of manufacturing a semiconductor structure according to claim 12, wherein the fin comprises one or more fin units; and
the accommodation groove corresponds to the fin unit in a one-to-one manner.

14. The method of manufacturing a semiconductor structure according to claim 13, the method of manufacturing a semiconductor structure further comprising:
removing the first oxide layer and the second oxide layer, and forming a channel groove.

15. The method of manufacturing a semiconductor structure according to claim 14, the method of manufacturing a semiconductor structure further comprising:
forming a third oxide layer, wherein the third oxide layer covers a bottom wall and sidewalls of the channel groove and an outer surface of the fin;
forming a barrier layer, wherein the barrier layer covers a bottom wall and partial sidewalls of the third oxide layer; and
forming a gate, wherein the gate covers a bottom wall and sidewalls of the barrier layer.
